(19) United States
(12) Patent Application Publication
(10) Pub. No.: US 2026/0242588 A1
(43) Pub. Date: Aug. 20, 2026

(54) THERMOPLASTIC RESIN COMPOSITION FOR ELECTROMAGNETIC WAVE ABSORBERS, AND MOLDED BODY

(71) Applicants: artience Co., Ltd., Tokyo (JP); TOYOCOLOR CO., LTD., Tokyo (JP); Microwave Absorbers Inc., Tokyo (JP)

(72) Inventors: Yuta KOBAYASHI, Tokyo (JP); Satoshi OGINO, Tokyo (JP); Masaki NISHIUCHI, Ehime (JP)

(73) Assignees: artience Co., Ltd., Tokyo (JP); TOYOCOLOR CO., LTD., Tokyo (JP); Microwave Absorbers Inc., Tokyo (JP)

(21) Appl. No.: 19/489,580

(22) PCT Filed: Jul. 12, 2024
(86) PCT No.: PCT/JP2024/025354

§ 371 Date: Dec. 2, 2025

(30) Foreign Application Priority Data
Jul. 14, 2023 (JP) 2023-116232

(51) Int. Cl. C08L 53/02; C08K 3/04

(52) U.S. Cl. CPC C08L 53/02; C08K 3/04

(57) ABSTRACT

One embodiment of the present invention relates to a thermoplastic resin composition for electromagnetic wave absorbers, the thermoplastic resin composition containing: 50% by mass to 80% by mass of an olefin-based elastomer (A) that has a tensile elongation at break of 400% to 700% as determined in accordance with ISO 37; 15% by mass to 35% by mass of an elastomer (B) that includes at least one elastomer which is selected from the group consisting of a styrene-based elastomer (B1) and an olefin-based elastomer (B2) that has a tensile elongation at break of 800% or more as determined in accordance with ISO 37; 0.5% by mass to 5% by mass of carbon nanotubes (C); and 3% by mass to 15% by mass carbon black (D).

### TECHNICAL FIELD

Embodiments of the invention relate to a thermoplastic resin composition for an electromagnetic wave absorber and a molded body.

### RELATED ART

Plastics are used in a wide range of fields such as electrical machine parts, electronic machine parts, automotive parts, medical parts, and food containers because they are easy to mold and process. Coloring of plastic molded bodies is actively performed to enhance decorativeness or to impart functionality. Particularly in the field of automotives, colored molded bodies for the purpose of electromagnetic wave absorption are distributed as those imparted with functionality.

Electromagnetic waves are radiated from communication apparatuses such as radios, televisions, and wireless communications, but in addition to this, electromagnetic waves are also radiated from electronic apparatuses such as mobile phones and personal computers, which have rapidly increased due to recent development in information technology. Conventionally, as a means to avoid malfunctioning caused by electromagnetic waves from electronic apparatuses, communication apparatuses, etc., electromagnetic wave absorbers that efficiently absorb electromagnetic waves and convert the absorbed electromagnetic waves into thermal energy have been installed near or far from electromagnetic wave generation sites.

An example of using an electromagnetic wave absorber installed far from the electromagnetic wave generation site is, for example, the application as an electronic toll collection (ETC) system on the highway. ETC is a system that exchanges billing information and other data using microwaves with a frequency of 5.8 GHz between a roadside antenna device installed at a toll booth and an in-vehicle antenna device in response to the vehicle passing through the highway toll booth exit. At the toll booth where the ETC system has been implemented, microwaves radiated from the antenna may be reflected off the roof of the toll booth and other structures, and unnecessary electromagnetic waves may leak from adjacent ETC lanes, causing communication abnormalities. Therefore, communication abnormalities are suppressed by installing electromagnetic wave absorber on the roof of the toll booth and between ETC lanes.

Also, in recent years, in the field of automotives, millimeter wave radars are used for the purpose of automatic driving and collision prevention of vehicles, and millimeter wave radar devices are commonly installed inside automobiles. Millimeter waves are electromagnetic waves with wavelengths of 1 mm to 10 mm and frequencies of 30 GHz to 300 GHz among electromagnetic waves. Currently, millimeter waves are used in vehicle-mounted radars, full-body scanners that see through clothing for security checks at airports and other locations, and video transmission of surveillance cameras on platforms during one-man train operation. A millimeter wave radar device is a device that can recognize obstacles by transmitting millimeter waves and receiving the waves that bounce back. Because the millimeter wave radar device has a long detectable distance and is less susceptible to interference from sunlight, rain, and fog, it is used today in automatic driving technology for automobiles and other applications. In the case as automotive sensors, millimeter wave radar devices can transmit and receive millimeter waves from antennas to detect relative distances and relative speeds with obstacles.

The transmitting and receiving antennas of the millimeter wave radar device may also receive waves reflected from the road surface and other objects other than the intended obstacle, which may reduce the detection accuracy of the device. To solve such issue, an electromagnetic wave absorber is provided as a shielding member that shields electromagnetic waves between the antenna and the control circuit in the millimeter wave radar device.

As an electromagnetic wave absorption material in the millimeter wave band that constitutes such electromagnetic wave absorber, carbon-based, metal-carbon-based, and magnetic material-based materials are known. For example, due to the high conductivity and relatively light weight, an electromagnetic wave absorber containing carbon nanotubes (CNT) as a carbon-based material is used (Patent Document 1).

### PRIOR ART DOCUMENT(S)

### Patent Document(s)

Patent Document 1: Japanese Patent Application Laid-open No. 2017-512847

### SUMMARY OF INVENTION

### Technical Problem

Patent Document 1 discloses a method of adding carbon nanotubes instead of conductive carbon black to improve conductivity while reducing the addition amount of the conductive filler in relation to the electromagnetic wave absorber. According to Patent Document 1, a composite material containing carbon nanotubes are said to have excellent conductivity and improved mechanical properties. However, in recent applications in the field of automotives, etc., further improvement is desired for the electromagnetic wave absorber.

Therefore, some embodiments of the invention have an object to provide a thermoplastic resin composition for an electromagnetic wave absorber that can render an electromagnetic wave absorber that exhibit favorable electromagnetic wave absorption properties and flexibility and further exhibit excellent heat resistance. Also, some embodiments of the invention have an object to provide a molded body having favorable electromagnetic wave absorption properties and flexibility and further exhibiting excellent heat resistance.

### Solution to Problem

As a result of intensive studies by the inventors, it is found that the issues of the invention can be solved in the following aspects, leading to the completion of the invention.

An embodiment of the invention relates to a thermoplastic resin composition for an electromagnetic wave absorber. The thermoplastic resin composition includes: 50% by mass to 80% by mass of Olefin Elastomer (A) having a tensile elongation rate at break of 400% to 700% measured according to ISO 37:2017; 15% by mass to 35% by mass of Elastomer (B) including at least one selected from a group consisting of Styrene Elastomer (B1) and Olefin Elastomer (B2) having a tensile elongation rate at break of 800% or more measured according to ISO 37:2017; 0.5% by mass to 5% by mass of Carbon Nanotube (C); and 3% by mass to 15% by mass of Carbon Black (D).

Another embodiment of the invention includes a molded body. The molded body is formed by using the thermoplastic resin composition for the electromagnetic wave absorber.

### Effects of Invention

According to some embodiments of the invention, with the thermoplastic resin composition for the electromagnetic wave absorber, electromagnetic wave absorbers having favorable electromagnetic wave absorption and flexibility and further having excellent heat resistance can be manufactured. According to some embodiments of the invention, the molded body exhibits favorable electromagnetic wave absorption and flexibility, and further exhibits excellent heat resistance.

### BRIEF DESCRIPTION OF DRAWINGS

FIG. 1 is a conceptual diagram of measurement of amounts of transmission attenuation and reflection attenuation by a millimeter wave transmission device.

### DESCRIPTION OF EMBODIMENTS

Hereinafter, the invention will be described in detail.

In the specification, numerical ranges specified with “~” include the numerical values described before and after “~” as the lower limit and upper limit of the range.
Also, “Olefin Elastomer (A) having a tensile elongation rate at break of 400 to 700% measured according to ISO 37:2017” may be referred to as “Olefin Elastomer (A)”, “Olefin Elastomer (B2) having a tensile elongation rate at break of 800% or more measured according to ISO 37:2017 may be referred to as “Olefin Elastomer (B2)”, “Elastomer (B) including at least one selected from the group consisting of Styrene Elastomer (B1) and Olefin Elastomer (B2)” may be referred to as “Elastomer (B)”, the thermoplastic resin composition for an electromagnetic wave absorber may be referred to as “thermoplastic resin composition”, and “carbon nanotubes” may be referred to as “CNT”.
Also, unless otherwise noted, various components appearing in the specification may each independently be used alone or in combination of two or more types.
The numerical values specified in the specification are values obtained by the methods disclosed in the embodiments or examples.

### <Thermoplastic Resin Composition for Electromagnetic Wave Absorber>

According to an embodiment of the invention, the thermoplastic resin composition for the electromagnetic wave absorber contains 50% by mass to 80% by mass of Olefin Elastomer (A) having a tensile elongation rate at break of 400 to 700% measured according to ISO 37:2017 (hereinafter referred to as “ISO37”), 15% by mass to 35% by mass of Elastomer (B) including at least one selected from the group consisting of Styrene Elastomer (B1) and Olefin Elastomer (B2) having a tensile elongation rate at break of 800% or more measured according to ISO37, 0.5% by mass to 5% by mass of carbon nanotube (C), and 3% by mass to 15% by mass of carbon black (D).

### [Olefin Elastomer (A)]

Olefin Elastomer (A) has a tensile elongation rate at break of 400% to 700% measured according to ISO37. In the case where the tensile elongation rate at break is 400% or more, the electromagnetic wave transmission efficiency between conductive fillers such as carbon nanotubes and carbon black is improved, which is preferable in terms of electromagnetic wave absorption and flexibility. The tensile elongation rate at break is preferably 500% or more, more preferably 550% or more, and still more preferably 600% or more. When the tensile elongation rate at break is 700% or less, it is preferable in terms of heat resistance. The tensile elongation rate at break is preferably 680% or less, more preferably 650% or less. The tensile elongation rate at break may be, for example, 400% to 700%, 500% to 680%, or 550% to 650%.

In the embodiment of the invention, the tensile elongation rate at break is a value obtained by measurement according to ISO37. Specifically, the measurement is performed on a test piece (dumbbell-shaped test piece No. 3 prepared according to JIS K 6251:2017) by using a material testing machine (for example, “3367” manufactured by Instron Corporation) under conditions of an atmosphere at a temperature of 23° C. and a tensile speed of 500 mm/min.

The melt mass flow rate (MFR) of Olefin Elastomer (A) is, for example, 0.1 g/10 min to 50 g/10 min. The MFR is preferably 5 g/10 min or more, more preferably 15 g/10 min or more, and still more preferably 20 g/10 min or more. Particularly when the MFR is 5 g/10 min or more, conductive fillers can be uniformly dispersed in the molded body, which is preferable in terms of electromagnetic wave absorption and moldability. The MFR is preferably 45 g/10 min or less, more preferably 40 g/10 min or less, and still more preferably 30 g/10 min or less. When the MFR is 50 g/10 min or less, it is preferable in terms of heat resistance. The melt mass flow rate (MFR) may be, for example, 5 g/10 min to 45 g/10 min, 15 g/10 min to 40 g/10 min, or 20 g/10 min to 30 g/10 min.

In the embodiment of the invention, the MFR is a value of the melt mass flow rate measured according to JIS K 7210:1999. Specifically, the measurement is performed by using a melt flow rate measuring machine (for example, “Melt Indexer” manufactured by Toyo Seiki Seisaku-sho, Ltd.) under the conditions of a temperature of 230° C. and a load of 2.16 kgf.

Olefin Elastomer (A) is preferably a mixed material in which a rubber component having elasticity is dispersed in polyolefin that is a molecular constraint component for preventing plastic deformation. The rubber component may be an uncrosslinked rubber component, a partially crosslinked rubber component, or a completely crosslinked rubber component. The crosslinking may be, for example, dynamic crosslinking performed during mixing and kneading of polyolefin and the rubber component. In the mixed material, a portion of polyolefin and the rubber component may be graft polymerized.

Examples of the polyolefin that is a molecular constraint component include crystalline polyolefins such as polyethylene and polypropylene. Examples of the rubber component include ethylene propylene rubber such as an ethylene-propylene copolymer (EPM), an ethylene-butylene copolymer (EBM), and an ethylene-propylene-diene terpolymer (EPDM), acrylonitrile butadiene rubber (NBR), and the like.

Olefin Elastomer (A) is preferably a dynamically crosslinked olefin thermoplastic elastomer in terms of heat resistance, and an elastomer that is dynamically crosslinked using crystalline polypropylene as a molecular constraint component and ethylene-propylene-diene terpolymer (EPDM) as a rubber component is preferable.

Examples of commercially available products of Olefin Elastomer (A) include Milastomer 9070NS, Milastomer L900NS, and Milastomer A970B manufactured by Mitsui Chemicals, Inc.; Actima-GA-1075N and Actima-LVG9541S manufactured by Riken Technos Corporation; Santoprene 201-87 and Santoprene 203-40 manufactured by ExxonMobil; Sarlink4190, Sarlink3190, and Sarlink4155 manufactured by Toyobo Co., Ltd.; EXCELINK1300B, EXCELINK1404B, and EXCELINK1309B manufactured by JSR Corporation; and the like.

The content of Olefin Elastomer (A) is 50% by mass to 80% by mass based on the mass of the thermoplastic resin composition. When the content is 50% by mass or more, it is preferable in terms of the manufacturing suitability of the thermoplastic resin composition and the molded body. The content is preferably 55% by mass or more, more preferably 60% by mass or more, and still more preferably 65% by mass or more. In the case where the content is 80% by mass or less, it is preferable in terms of electromagnetic wave absorption. The content is preferably 75% by mass or less, more preferably 70% by mass or less, and still more preferably 70% by mass or less. The content may be, for example, 55% by mass to 75% by mass, 60% by mass to 70% by mass, or 65% by mass to 70% by mass.

### [Elastomer (B)]

The thermoplastic resin composition contains Elastomer (B) that includes at least one selected from the group consisting of Styrene Elastomer (B1) and Olefin Elastomer (B2). Elastomer (B) may be Styrene Elastomer (B1), Olefin Elastomer (B2), or both Styrene Elastomer (B1) and Olefin Elastomer (B2).

### (Styrene Elastomer (B1))

Styrene Elastomer (B1) may be a block copolymer of styrene and at least one selected from the group consisting of α-olefin and diolefin. The styrene may be substituted or unsubstituted, and is preferably unsubstituted. Examples of α-olefin are as described below. Examples of diolefin (diene) include 1,3-butadiene, isoprene, 2,3-dimethyl-1,3-butadiene, 1,3-pentadiene, and the like. Styrene Elastomer (B1) may be a styrene thermoplastic elastomer, and may be a hydrogenated styrene thermoplastic elastomer.

In Styrene Elastomer (B1), the content of the styrene structure is, for example, 10% by mass to 50% by mass based on the mass of Styrene Elastomer (B1), preferably 15% by mass to 35% by mass, and more preferably 20% by mass to 32% by mass. When the content of the styrene structure is 15% by mass or more, the ratio of the styrene structure that is a hard segment increases, which is preferable in terms of heat resistance. The content of the styrene structure is preferably 18% by mass or more, more preferably 20% by mass or more, and still more preferably 25% by mass or more. When the content of the styrene structure is 35% by mass or less, the ratio of the α-olefin structure that is a soft segment becomes high, which is preferable in terms of flexibility. Moreover, since compatibility with Olefin Elastomer (A) is improved, it is preferable in terms of electromagnetic wave absorption. The content of the styrene structure is preferably 34% by mass or less, more preferably 32% by mass or less, and still more preferably 30% by mass or less.

Styrene Elastomer (B1) includes, for example, a styrene structure and at least one selected from the group consisting of an α-olefin structure and a diolefin structure. The diolefin structure may be hydrogenated or may not be hydrogenated.

In Styrene Elastomer (B1), the content of the α-olefin structure and the diolefin structure is, for example, 50% by mass to 85% by mass based on the mass of Styrene Elastomer (B1). From the viewpoint of flexibility, the content of the α-olefin structure and the diolefin structure is preferably 55% by mass or more, more preferably 60% by mass or more, and still more preferably 65% by mass or more. From the viewpoint of heat resistance, the content of the α-olefin structure and the diolefin structure is preferably 80% by mass or less, more preferably 75% by mass or less, and still more preferably 70% by mass or less. The content may be, for example, 50% by mass to 80% by mass, 55% by mass to 75% by mass, or 60% by mass to 70% by mass. The “content of the α-olefin structure and the diolefin structure” is the total content of both in the case where Styrene Elastomer (B1) includes both the α-olefin structure and the diolefin structure, and, in the case where Styrene Elastomer (B1) includes only one of the α-olefin structure and the diolefin structure, the content is the content of the one of the α-olefin structure and the diolefin structure.

The solution viscosity of Styrene Elastomer (B1) is, for example, 30 mPa·s or more, preferably 50 mPa·s or more, more preferably 100 mPa·s or more, and still more preferably 200 mPa·s or more. When the solution viscosity is 30 mPa·s or more, it is preferable in terms of heat resistance. The solution viscosity has no particular upper limit, but may be 1,000 mPa·s or less or 500 mPa·s or less from the viewpoint of compatibility with Olefin Elastomer (A). The solution viscosity may be, for example, 30 mPa·s to 1,000 mPa·s, 50 mPa·s to 1,000 mPa·s, 100 mPa·s to 500 mPa·s, or 200 mPa·s to 500 mPa·s.

In the embodiment of the invention, the solution viscosity of Styrene Elastomer (B1) is a value measured using a B-type viscometer in an atmosphere at a temperature of 30° C., using a toluene solution obtained by dissolving Styrene Elastomer (B1) in a toluene solvent to a concentration of 5% by mass. As the B-type viscometer, for example, “VISCOMETER TVB-10” manufactured by Toki Sangyo Co., Ltd. can be used.

The weight average molecular weight of Styrene Elastomer (B1) is, for example, 10,000 or more, from the viewpoint of heat resistance, preferably 50,000 or more, more preferably 80,000 or more, and still more preferably 100,000 or more. Also, from the viewpoint of compatibility with Olefin Elastomer (A), it is preferably 800,000 or less, more preferably 600,000 or less, and still more preferably 500,000 or less. The weight average molecular weight is a value in terms of standard polystyrene measured by gel permeation chromatography (GPC). The weight average molecular weight may be, for example, 50,000 to 800,000, 80,000 to 600,000, or 100,000 to 500,000.

The Shore A hardness of Styrene Elastomer (B1) is preferably 80 or less, more preferably 70 or less, and still more preferably 60 or less from the viewpoint of flexibility. In the specification, unless otherwise specified, Shore A hardness is a value measured by using a durometer with a Type A indenter in accordance with JIS K6253.

Styrene Elastomer (B1) may be, for example, any of the following block copolymers. Styrene Elastomer (B1) is preferably a block copolymer of a styrene structure as a hard segment and an α-olefin structure as a soft segment from the viewpoint of heat resistance.

Styrene Elastomer (B1) is preferably a block copolymer of a styrene structure as a hard segment and an α-olefin structure and a diolefin (diene) structure as soft segments from the viewpoint of heat resistance. The diolefin (diene) structure may be hydrogenated or non-hydrogenated, and is preferably a hydrogenated diolefin (diene) structure.
Styrene Elastomer (B1) is preferably a block copolymer of a styrene structure as a hard segment and a hydrogenated polydiene structure as a soft segment from the viewpoint of heat resistance.

Examples of Styrene Elastomer (B1) include styrene-ethylene-butylene-styrene block copolymers (SEBS), styrene-ethylene-propylene block copolymers (SEP), styrene-ethylene-propylene-styrene block copolymers (SEPS), styrene-ethylene-ethylene-propylene-styrene block copolymers (SEEPS), styrene-butadiene-styrene block copolymers (SBS), styrene-butadiene-styrene-butadiene block copolymers (SBSB), styrene-butadiene-butylene-styrene block copolymers (SBBS), and the like. Styrene Elastomer (B1) preferably includes at least one selected from the group consisting of styrene-ethylene-butylene-styrene block copolymers (SEBS), styrene-ethylene-propylene block copolymers (SEP), styrene-ethylene-propylene-styrene block copolymers (SEPS), and styrene-ethylene-ethylene-propylene-styrene block copolymers (SEEPS). From the viewpoint of heat resistance, electromagnetic wave absorption, and moldability, the thermoplastic resin composition more preferably includes at least one selected from the group consisting of styrene-ethylene-butylene-styrene block copolymers (SEBS), styrene-ethylene-propylene-styrene block copolymers (SEPS), and styrene-ethylene-ethylene-propylene-styrene block copolymers (SEEPS), and still more preferably includes at least one selected from the group consisting of styrene-ethylene-butylene-styrene block copolymers (SEBS) and styrene-ethylene-ethylene-propylene-styrene block copolymers (SEEPS).

Examples of commercially available products of Styrene Elastomer (B1) include Septon 4077, Septon 4055, Septon 8006, Septon 4044, and Septon 2005 manufactured by Kuraray Co., Ltd.; Tuftec H1221, Tuftec H1041, and Tuftec H1051 manufactured by Asahi Kasei Chemicals Corporation; and Kraton G1643M, Kraton G1645M, and Kraton G1652H manufactured by Kraton Polymers LLC.

The content of Styrene Elastomer (B1) is 15% by mass to 35% by mass based on the mass of the thermoplastic resin composition. When the content is 15% by mass or more, it is preferable from the viewpoint of flexibility. The content is preferably 16% by mass or more, more preferably 18% by mass or more, and still more preferably 20% by mass or more. In the case where the content is 35% by mass or less, it is preferable from the viewpoint of heat resistance and electromagnetic wave absorption. The content is preferably 30% by mass or less, more preferably 25% by mass or less, and still more preferably 23% by mass or less. When the thermoplastic resin composition contains Styrene Elastomer (B1), heat resistance is improved. The content may be, for example, 16% by mass to 30% by mass, 18% by mass to 25% by mass, or 20% by mass to 23% by mass.

### (Olefin Elastomer (B2))

Olefin Elastomer (B2) has a tensile elongation rate at break of 800% or more as measured according to ISO37. When the tensile elongation rate at break is 800% or more, it is preferable from the points of flexibility and electromagnetic wave absorption. The tensile elongation rate at break is preferably 1,000% or more. The tensile elongation rate at break has no particular upper limit, but may be 1,500% or less. The tensile elongation rate at break may be 800% to 1,500% or 1,000% to 1,500%.

Olefin Elastomer (B2) is preferably an uncrosslinked or partially crosslinked elastomer, more preferably an uncrosslinked elastomer, and may be, for example, a homopolymer of olefin or a copolymer of olefin. The copolymer of olefin is, for example, a copolymer of at least two kinds of α-olefin, and may be a copolymer of ethylene and α-olefin, and further may be a copolymer of ethylene and at least one kind of α-olefin having 3 or more carbon atoms. Olefin Elastomer (B2) may be a copolymer of olefin and maleic acid, a copolymer of olefin and (meth)acrylic acid ester, or the like.

Examples of the α-olefin include ethylene, propylene, 1-butene, 2-methyl-1-propene, 2-methyl-1-butene, 3-methyl-1-butene, 1-hexene, 2-ethyl-1-butene, 2,3-dimethyl-1-butene, 2-methyl-1-pentene, 3-methyl-1-pentene, 4-methyl-1-pentene, 3,3-dimethyl-1-butene, 1-heptene, methyl-1-hexene, dimethyl-1-pentene, ethyl-1-pentene, trimethyl-1-butene, methylethyl-1-butene, 1-octene, methyl-1-pentene, ethyl-1-hexene, dimethyl-1-hexene, propyl-1-heptene, methylethyl-1-heptene, trimethyl-1-pentene, propyl-1-pentene, diethyl-1-butene, 1-nonene, 1-decene, 1-undecene, 1-dodecene, and the like.

The α-olefin preferably includes 1-butene, which is easily available commercially and excels in flexibility.

The melt mass flow rate (MFR) of Olefin Elastomer (B2) is, for example, 0.1 g/10 min to 50 g/10 min. The MFR is preferably 3 g/10 min or more, more preferably 5 g/10 min or more, and may be further 20 g/10 min or more. In particular, when the MFR is 3 g/10 min or more, it is preferable from the point of electromagnetic wave absorption. The MFR is preferably 20 g/10 min or less, more preferably 10 g/10 min or less. In particular, when the MFR is 20 g/10 min or less, it is preferable from the points of moldability and heat resistance. The MFR may be, for example, 3 g/10 min to 20 g/10 min or 5 g/10 min to 10 g/10 min.

Examples of Olefin Elastomer (B2) include ethylene-propylene copolymers, ethylene-butene-1 copolymers, ethylene-hexene-1 copolymers, ethylene-octene-1 copolymers, ethylene-ethyl acrylate copolymers, ethylene-methacrylate copolymers, propylene-ethylene-1-butene copolymers, ethylene-1-butene copolymers, polybutene, polyisobutylene, maleic acid-modified products thereof, and the like. Since it is easily available, Olefin Elastomer (B2) is preferably a propylene-ethylene-1-butene copolymer.

Examples of commercially available products of Olefin Elastomer (B2) include Tafmer PN-3560, MH-5010, PN-20300, MA9015, XM-7090 manufactured by Mitsui Chemicals; ENGAGE8130, ENGAGE8200, ENGAGE8400 manufactured by Dow Chemical, and the like.

The content of Olefin Elastomer (B2) is 15% by mass to 35% by mass based on the mass of the thermoplastic resin composition. When the content is 15% by mass or more, it is preferable from the point of flexibility. The content is preferably 16% by mass or more, more preferably 18% by mass or more, and further preferably 20% by mass or more. When the content is 35% by mass or less, it is preferable from the points of heat resistance and electromagnetic wave absorption. The content is preferably 30% by mass or less, more preferably 25% by mass or less, and further preferably 23% by mass or less. The content may be, for example, 16% by mass to 30% by mass, 18% by mass to 25% by mass, or 20% by mass to 23% by mass.

Styrene Elastomer (B1) and Olefin Elastomer (B2) can be used in combination, but in the case where Styrene Elastomer (B1) and Olefin Elastomer (B2) are together, from the points of flexibility and heat resistance, Olefin Elastomer (B2) is preferably less than 100% by mass, and more preferably 50% by mass or less, relative to 100% by mass of Styrene Elastomer (B1).

The content of Elastomer (B) is 15% by mass to 35% by mass based on the mass of the thermoplastic resin composition. When the content is 15% by mass or more, it is preferable from the point of flexibility. The content is preferably 16% by mass or more, more preferably 18% by mass or more, and further preferably 20% by mass or more. When the content is 35% by mass or less, it is preferable from the points of heat resistance and electromagnetic wave absorption. The content is preferably 30% by mass or less, more preferably 25% by mass or less, and further preferably 23% by mass or less. The “content of Elastomer (B)” is the total content of both Styrene Elastomer (B1) and Olefin Elastomer (B2) when Elastomer (B) contains Styrene Elastomer (B1) and Olefin Elastomer (B2), and when Elastomer (B) contains only one of Styrene Elastomer (B1) and Olefin Elastomer (B2), the “content of Elastomer (B)” is the one of Styrene Elastomer (B1) and Olefin Elastomer (B2). The content may be, for example, 16% by mass to 30% by mass, 18% by mass to 25% by mass, or 20% by mass to 23% by mass.

### [Carbon Nanotube (C)]

Carbon nanotube (C) may be a single-walled carbon nanotube, a multi-walled carbon nanotube wound with two or more layers, or a mixture thereof, but is preferably a multi-walled carbon nanotube from the viewpoints of cost and strength. 1. Additionally, carbon nanotubes having sidewalls with an amorphous structure rather than a graphite structure may be used.

Carbon nanotubes (C) can generally be produced by the laser ablation method, the arc discharge method, the chemical vapor deposition (CVD) method, the combustion method, and the like, but carbon nanotubes produced by any method may be used. In particular, the CVD method is a method that can produce carbon nanotubes massively and inexpensively by bringing catalyst fine particles, in which a metal catalyst such as iron and nickel is supported on a carrier such as silica, alumina, magnesium oxide, titanium oxide, silicate, diatomaceous earth, alumina silica, silica titania, and zeolite, into contact with a carbon-containing gas as a raw material, usually at a high temperature of 400° C. to 1000° C., and is also preferable as the carbon nanotube used in the embodiment of the invention.

Carbon Nanotubes (C) preferably have an average diameter of 1 nm to 30 nm determined by a scanning-type electron microscope, more preferably 2 nm to 25 nm, and further preferably 5 nm to 20 nm. According to the range, the dispersibility of the carbon nanotube in the thermoplastic resin composition is high, and the molded body excels in electromagnetic wave absorption performance.

The average diameter of the carbon nanotubes is determined by using a scanning-type electron microscope (for example, JSM-6700M manufactured by JEOL Ltd.). The conditions are as follows: the carbon nanotubes are observed at an acceleration voltage of 5 kV, and a 50,000× magnification image (1024×1280 pixels) is captured, then the length of the short axis of each of 20 arbitrary carbon nanotubes in the captured image is measured, and the numerical average of the lengths of the short axes is calculated as the average diameter of the carbon nanotubes.

Examples of commercially available carbon nanotubes include CM-130 and CM-250 manufactured by Hanhwa Chemical hanos; SNW210 manufactured by South West NanoTechnologies; Flotube 7000 and Flotube 3100 manufactured by CNano; and GraphistrengthC100 manufactured by Arkema.

The content of Carbon Nanotubes (C) is 0.5% by mass to 5% by mass based on the mass of the thermoplastic resin composition. When the content is 0.5% by mass or more, the electromagnetic wave transmission in the molded body becomes smooth, which is preferable in terms of electromagnetic wave absorption (particularly transmission loss) and also preferable in terms of heat resistance. When the content is 5% by mass or less, electromagnetic waves are easily incorporated at the molded body surface, which is preferable in terms of electromagnetic wave absorption (particularly reflection loss) and also preferable in terms of flexibility. The content is preferably 1% by mass or more, more preferably 1.5% by mass or more. The content is preferably 4% by mass or less, more preferably 3% by mass or less. The content may be, for example, 1% by mass to 4% by mass or 1.5% by mass to 3% by mass.

### [Carbon Black (D)]

As Carbon Black (D), various types can be used alone, or multiple types can be used in combination, including furnace black produced by continuously thermally decomposing gaseous or liquid raw materials in a reaction furnace, particularly Ketjen black using ethylene heavy oil as a raw material, channel black produced by burning raw material gas and rapidly cooling the flame by applying it to the bottom surface of the channel steel to precipitate, thermal black obtained by periodically repeating combustion and thermal decomposition using gas as a raw material, and acetylene black particularly using acetylene gas as a raw material. Commonly used oxidation-treated carbon black and hollow carbon can also be used.

Carbon Black (D) preferably has an average primary particle diameter of 20 nm to 60 nm as determined by the scanning-type electron microscope, more preferably 30 nm to 50 nm, and even more preferably 35 nm to 45 nm. In the range, after injection molding or extrusion molding, Carbon Nanotubes (C) incorporated inside the molded body can effectively form a conductive path with each other, making it possible to stably exhibit high conductivity and electromagnetic wave absorption.

The average primary particle diameter of the carbon black is specifically determined by using, for example, a scanning-type electron microscope (JSM-6700M, manufactured by JEOL Ltd.). The conditions are as follows: carbon black is observed at an acceleration voltage of 5 kV, and a 50,000× magnification image (1024×1280 pixels) is captured. Then, the particle diameter of each of the 20 arbitrary carbon black particles in the captured image is measured, and the numerical average of the measurements is calculated as the average primary particle diameter of the carbon black.

Examples of commercially available carbon black include, but are not limited to, furnace black manufactured by Nippon Steel Chemical Co., Ltd., such as Niteron #10, #200, and #300; furnace black manufactured by Tokai Carbon Co., Ltd., such as Tokablock #4300, #4400, #4500, and #5500; furnace black manufactured by Degussa such as Printex L; furnace black manufactured by Columbian such as Raven 7000, 5750, 5250, 5000 ULTRA III, 5000 ULTRA, Conductex SC ULTRA, 975 ULTRA, PUER BLACK 100, 115, and 205; furnace black manufactured by Mitsubishi Chemical Corporation such as #30B, #45, #2350, #2400B, #2600B, #30050B, #3030B, #3230B, #3350B, #3400B, and #5400B; furnace black manufactured by Cabot Corporation such as MONARCH 1400, 1300, 900, Vulcan XC-72R, and Black Pearls 2000; furnace black manufactured by Imerys such as Ensaco 250G, Ensaco 260G, Ensaco 350G, and Super P-Li; Ketjen black manufactured by Akzo such as Ketjen Black EC-300J and EC-600JD; acetylene black manufactured by Denka Company Limited such as Denka Black HS-100 and FX-35; and Ketjen black manufactured by Lion Specialty Chemicals Co., Ltd., such as Carbon ECP and Carbon ECP600JD.

The content of Carbon Black (D) is 3% by mass to 15% by mass based on the mass of the thermoplastic resin composition. When the content is 3% by mass or more, electromagnetic wave transmission within the molded body becomes smooth, which is preferable in terms of electromagnetic wave absorption (particularly transmission loss) and also preferable in terms of heat resistance. When the content is 15% by mass or less, electromagnetic waves are easily incorporated at the surface of the molded body, which is preferable in terms of electromagnetic wave absorption (particularly reflection loss) and also preferable in terms of flexibility. The content is preferably 5% by mass or more, more preferably 7% by mass or more. The content is preferably 12% by mass or less, more preferably 10% by mass or less. The content may be, for example, 5% by mass to 12% by mass or 7% by mass to 12% by mass.

The content ratio of Carbon Nanotube (C) to Carbon Black (D) is preferably Carbon Nanotube (C)/Carbon Black (D)=1/2 to 1/7, more preferably ⅓ to 1/5. Within the range, it becomes possible to achieve both reflection loss and transmission loss in electromagnetic wave absorption.

### [Other Optional Components]

The thermoplastic resin composition can use other optional components such as polymers other than Olefin Elastomer (A) and Elastomer (B), electromagnetic wave absorbing materials, weather stabilizers, antistatic agents, dyes, pigments, coupling agents, crystal nucleating agents, resin fillers, and the like, as necessary.

The thermoplastic resin composition preferably does not contain a volatile component. In 100% by mass of the thermoplastic resin composition, a volatile component such as a solvent or a low molecular weight component is preferably 5% by mass or less, more preferably 1% by mass or less.

### [Method for Producing Thermoplastic Resin Composition]

The method for producing the thermoplastic resin composition is not particularly limited. For example, Olefin Elastomer (A), Elastomer (B), Carbon Nanotube (C), Carbon Black (D), and further additives can be added as necessary and mixed by using a Henschel mixer, a tumbler, a disperser, or the like, and then mixed or melt-kneaded using a kneader, a roll mill, a super mixer, a Henschel mixer, a Schugi mixer, a vertical granulator, a high-speed mixer, a Pharmatrix, a ball mill, a steel mill, a sand mill, a vibration mill, an attritor, a batch-type kneading machine such as a Banbury mixer, a twin-screw extruder, a single-screw extruder, a rotor-type twin-screw kneader, or the like to obtain a resin composition in the form of pellets, powder, granules, beads, or the like. It is preferable to use a twin-screw extruder for melt-kneading.

### <Molded Body>

According to an embodiment of the invention, the molded body is formed by using the thermoplastic resin composition of the embodiment and used for an electromagnetic wave absorber. The molded body can be obtained by melting the thermoplastic resin composition in a molding machine to form the shape of the molded body and cooling the molded body. The temperature of the molding machine is not problematic as long as it is a temperature at which Olefin Elastomer (A) and Elastomer (B) are softened, but is preferably a temperature 30° C. or higher than the softening point of Olefin Elastomer (A) and Elastomer (B). It is preferable that shapes such as plates, rods, fibers, tubes, pipes, bottles, films, and the like can be obtained as the shape of the molded body.

As the molding method, for example, extrusion molding, injection molding, blow molding, compression molding, transfer molding, film molding such as T-die molding or inflation molding, calendar molding, spinning, and the like can be used.

The electromagnetic wave absorber absorbs incident electromagnetic wave energy by converting the energy into thermal energy inside the absorber. Unlike electromagnetic wave shielding materials, the electromagnetic wave absorber aims to absorb electromagnetic waves inside the molded body without reflecting the electromagnetic waves at the surface of the molded body. The electromagnetic wave absorber is used in the automotive field such as electronic toll collection systems (ETC) on highways and vehicle-mounted radars, whole-body scanners that see through clothing for security checks at airports and the like, millimeter wave radar devices used for video transmission of surveillance cameras on platforms during one-man train operation, and radar ghost prevention for ship masts. Among these, the molded body formed from the thermoplastic resin composition in the embodiment of the invention is excellent in electromagnetic wave absorption performance in the millimeter wave band of 60 GHz frequency to 90 GHz frequency, and therefore can be suitably used in millimeter wave radar devices.

### Examples of Embodiments

The invention includes, for example, the following embodiments. The embodiments of the invention are not limited to the following examples.
(1) A thermoplastic resin composition for an electromagnetic wave absorber includes: 50% by mass to 80% by mass of Olefin Elastomer (A) having a tensile elongation rate at break of 400% to 700% measured according to ISO 37:2017; 15% by mass to 35% by mass of Elastomer (B) including at least one selected from the group consisting of Styrene Elastomer (B1) and Olefin Elastomer (B2) having a tensile elongation rate at break of 800% or more measured according to ISO 37:2017; 0.5% by mass to 5% by mass of Carbon Nanotube (C); and 3% by mass to 15% by mass of Carbon Black (D).
(2) In the thermoplastic resin composition for the electromagnetic wave absorber according to (1), Elastomer (B) includes Styrene Elastomer (B1), and Styrene Elastomer (B1) includes at least one selected from the group consisting of a styrene-ethylene-butylene-styrene block copolymer (SEBS), a styrene-ethylene-propylene block copolymer (SEP), a styrene-ethylene-propylene-styrene block copolymer (SEPS), and a styrene-ethylene-ethylene-propylene-styrene block copolymer (SEEPS).
(3) In the thermoplastic resin composition for the electromagnetic wave absorber according to (1) or (2) above, Elastomer (B) includes Styrene Elastomer (B1), and the content of a styrene structure in Styrene Elastomer (B1) is 15% by mass to 35% by mass.
(4) In the thermoplastic resin composition for the electromagnetic wave absorber according to any one of (1) to (3) above, Elastomer (B) includes Olefin Elastomer (B2), and Olefin Elastomer (B2) includes an ethylene-α-olefin copolymer.
(5) A molded body is molded by using the thermoplastic resin composition for the electromagnetic wave absorber according to any one of (1) to (4) above.

The disclosure of the present application is related to the subject matter described in Japanese Patent Application No. 2023-116232 filed on Jul. 14, 2023, the entire disclosed contents of which are incorporated herein by reference.

### EXAMPLES

The invention will be described in more detail below by way of examples, but the following examples do not limit the invention in any way. In the examples, “parts” represents “parts by mass” and “%” represents “% by mass”. Also, the blending amounts in the tables are % by mass, and blank spaces in the tables indicate that no blending is performed.

The tensile elongation rate at break and the MFR of Olefin Elastomer (A) and Olefin Elastomer (B2), the solution viscosity and the weight average molecular weight of Styrene Elastomer (B1), the average diameter of Carbon Nanotube (C), and the average primary particle diameter of Carbon Black (D) were measured by the following methods.

### (Tensile Elongation Rates at Break of Olefin Elastomer (A) and Olefin Elastomer (B2))

The tensile elongation rate at break was measured according to ISO37. Specifically, measurements were performed on test specimens (dumbbell-shaped No. 3 test specimens prepared according to JIS K 6251:2017) prepared by using elastomer, through using a material testing machine “3367” manufactured by Instron Corporation under conditions of an atmosphere at a temperature of 23° C. and a tensile speed of 500 mm/min.

### (Melt Mass Flow Rates (MFR) of Olefin Elastomer (A) and Olefin Elastomer (B2))

MFR was measured according to JIS K 7210:1999. Specifically, measurements were performed by using a “Melt Indexer” manufactured by Toyo Seiki Seisaku-sho, Ltd. under the conditions of a temperature of 230° C. and a load of 2.16 kgf.

### (Solution Viscosity of Styrene Elastomer (B1))

The solution viscosity was measured by using a solution obtained by dissolving Styrene Elastomer (B1) in a toluene solvent to a concentration of 5% by mass, through using a “B-type viscometer VISCOMETER TVB-10” manufactured by Toki Sangyo Co., Ltd. in an atmosphere at a temperature of 30° C.

### (Weight Average Molecular Weight of Styrene Elastomer (B1))

The weight average molecular weight was measured by using LC Solution (manufactured by SHIMADZU). THF was used as an eluent and adjusted to 2 mg/mL, 10 μL of a measurement sample solution was injected into the apparatus, and under the conditions of a column oven temperature of 40° C. and a THF flow rate of 1 mL/min, a differential refractometer RID-10A (manufactured by SHIMADZU) was used as the detector. For the columns, two TSK gel G4000 Hxl columns in series (manufactured by TOSOH) were used, and for the guard column, a TSK guard column Hxl-L (manufactured by TOSOH) was used.

### (Average Diameter of Carbon Nanotube (C))

Carbon nanotubes were observed at an acceleration voltage of 5 kV by using a scanning-type electron microscope (manufactured by JEOL Ltd., JSM-6700M), and an image at 50,000× magnification (pixel count 1024×1280) was captured. Next, for 20 arbitrary carbon nanotubes in the captured image, the length of the short axis of each nanotube was measured, and the numerical average of the lengths of the short axes was taken as the average diameter of the carbon nanotubes.

### (Average Primary Particle Diameter of Carbon Black (D))

Carbon black was observed at an acceleration voltage of 5 kV by using a scanning-type electron microscope (manufactured by JEOL Ltd., JSM-6700M), and an image at 50,000× magnification (pixel count 1024×1280) was captured. Next, for 20 arbitrary carbon black particles in the captured image, the particle diameter of each was measured, and the numerical average of the particle diameters was taken as the average primary particle diameter of the carbon black.

Materials used in Examples and Comparative Examples are as follows.

### (Olefin Elastomer (A))

TABLE 1

| | | | | Tensile | |
|---|---|---|---|---|---|
| | | | | elonga- | |
| | | | | tion | MFR |
| | | | | rate | (g/10 |
| | Product Name | | Structure | (%) | min) |
| A-1 | MILASTOMER | By Mitsui | dynamic | 620 | 25 |
| | 9070NS | Chemicals, | crosslinked | | |
| | | Inc. | olefin | | |
| | | | thermoplastic | | |
| | | | elastomer | | |
| A-2 | MILASTOMER | By Mitsui | dynamic | 460 | 18 |
| | L900NS | Chemicals, | crosslinked | | |
| | | Inc. | olefin | | |
| | | | thermoplastic | | |
| | | | elastomer | | |
| A-3 | MILASTOMER | By Mitsui | dynamic | 530 | 0.3 |
| | A970B | Chemicals, | crosslinked | | |
| | | Inc. | olefin | | |
| | | | thermoplastic | | |
| | | | elastomer | | |
| A′-1 | ACTYMER G | RIKEN | dynamic | 310 | — |
| | GA-1045N | TECHNOS | crosslinked | | |
| | | CORP. | olefin | | |
| | | | thermoplastic | | |
| | | | elastomer | | |

### (Styrene Elastomer (B1))

TABLE 2-1

| | | | | | α-olefin and | | Weight |
|---|---|---|---|---|---|---|---|
| | | | | Styrene | diolefin | Solution | average |
| | | | | content | content | viscosity | molecular |
| | Product name | | Structure | (%) | (%) | <mPa · s> | weight |
| B1-1 | Septon 4077 | By Kuraray | SEEPS | 30 | 70 | 300 | 380,000 |
| | | Corporation | | | | | |
| B1-2 | Septon 4055 | By Kuraray | SEEPS | 30 | 70 | 90 | 300,000 |
| | | Corporation | | | | | |
| B1-3 | Septon 8006 | By Kuraray | SEBS | 33 | 67 | 42 | 300,000 |
| | | Corporation | | | | | |
| B1-4 | Septon 2005 | By Kuraray | SEPS | 20 | 80 | 40 | 80,000 |
| | | Corporation | | | | | |
| B1-5 | Septon 4044 | By Kuraray | SEEPS | 30 | 70 | 22 | 200,000 |
| | | Corporation | | | | | |
| B1-6 | Tuftec H1221 | By Asahi | SEBS | 12 | 88 | 35 | 100,000 |
| | | Kasei | | | | | |
| | | Corporation | | | | | |
| B1-7 | Tuftec H1051 | By Asahi | SEBS | 42 | 58 | over 500 | 70,000 |
| | | Kasei | | | | | |
| | | Corporation | | | | | |
| B1-8 | Asaprene T-411 | By Asahi | SBS | 30 | 70 | over 500 | 430,000 |
| | | Kasei | | | | | |
| | | Corporation | | | | | |

### (Olefin Elastomer (B2))

TABLE 2-2

| | | | | Tensile | |
|---|---|---|---|---|---|
| | | | | elongation | MFR |
| | | | | rate | (g/10 |
| | Product name | | Structure | (%) | min) |
| B2-1 | Tafmer | manufactured | propylene- | over 1,000 | 6.0 |
| | PN-3560 | by Mitsui | ethylene-1-butene | | |
| | | Chemicals, Inc. | copolymer | | |
| B2-2 | Tafmer | manufactured | maleic acid- | over 1,000 | 0.6 |
| | MH-5020 | by Mitsui | modified | | |
| | | Chemicals, Inc. | ethylene-butene | | |
| | | | copolymer | | |
| B2-3 | Tafmer | manufactured | propylene- | over 1,000 | 30 |
| | PN-20300 | by Mitsui | ethylene-1-butene | | |
| | | Chemicals, Inc. | copolymer | | |
| B2-4 | Tafmer | manufactured | maleic acid- | 850 | 23 |
| | MA9015 | by Mitsui | modified | | |
| | | Chemicals, Inc. | ethylene-butene | | |
| | | | copolymer | | |
| B2′-1 | Tafmer | manufactured | propylene- | 750 | 7.0 |
| | XM-7090 | by Mitsui | ethylene-1-butene | | |
| | | Chemicals, Inc. | copolymer | | |

### (Carbon Nanotube (C))

TABLE 3

| | | | Average diameter |
|---|---|---|---|
| | Product name | | (nm) |
| C-1 | CM-130 | By Hanwha Chemical Hanos | 15 |
| C-2 | SNW210 | By South West Nano Technologies | 9 |
| C-3 | Flotube | By CNano | 6 |
| | 7000 | | |

### (Carbon Black (D))

TABLE 4

| | | | | Average primary |
|---|---|---|---|---|
| | | | | particle diameter |
| | Product name | | Type | (nm) |
| D-1 | Niteron 10 | By Nippon Steel | furnace | 39 |
| | | Carbon Co., Ltd. | black | |
| D-2 | carbon ECP | By Lion Specialty | Ketjen | 40 |
| | | Chemicals | black | |
| D-3 | Ensaco 250G | By TIMCAL | furnace | 45 |
| | | | black | |

### <Production of Thermoplastic Resin Composition>

### Example 1

Olefin Elastomer (A-1), Styrene Elastomer (B1-1), Carbon Nanotube (C-1), and Carbon Black (D-1) were mixed in the blending amounts (% by mass) shown in Table 5, melt-kneaded, extruded at 230° C. by using a twin-screw extruder (manufactured by Japan Steel Works, Ltd.), and granulated to obtain a thermoplastic resin composition.

### Examples 2 to 22 and Comparative Examples 1 to 8

Thermoplastic resin compositions were obtained by the same method as Example 1, except that the materials and blending amounts (% by mass) were changed to those shown in Tables 5 to 7, respectively.

### <Evaluation of Thermoplastic Resin Compositions>

The obtained thermoplastic resin compositions were evaluated by the following methods. The results are shown in Tables 5 to 7.

### [Preparation of Molded Body]

By using the thermoplastic resin composition, injection molding was performed with an injection molding machine (manufactured by Toshiba Machine Co., Ltd.) at a cylinder set temperature of 220° C. and a mold temperature of 40° C. to prepare a molded body having dimensions of 90 mm in length (injection direction), 110 mm in width (direction perpendicular to the injection direction), and 3 mm in thickness.

### [Electromagnetic Wave Absorption Performance]

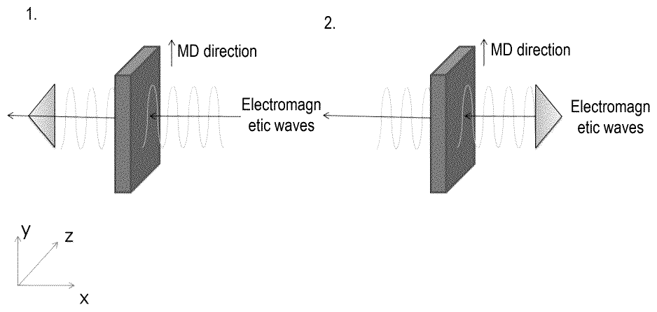

FIG. 1 shows the electromagnetic wave irradiation direction (x), electric field direction (y), and magnetic field direction (z) when electromagnetic waves are incident on the molded body in the thickness direction, where “1.” is a conceptual diagram for measuring transmission loss TL(MD), and “2.” is a conceptual diagram for measuring reflection loss RL(MD). As shown in “1.” and “2.” of FIG. 1, after allowing the obtained molded body to stand for one day, reflection loss RL(MD) and transmission loss TL(MD) were measured in a state where the electric field direction of the electromagnetic wave (y direction in the FIGURE) was parallel to the injection direction (MD direction).

### (Reflection Loss RL)

As an indicator of electromagnetic wave absorption performance, reflection loss (dB) in the millimeter wave frequency band was measured by the following method. A vector network analyzer (VNA) was used as the measuring instrument, APC-7 (manufactured by Kanto Electronics Application and Development Inc.) was used as the measurement jig, and an E-band antenna (WR-12) was used as the antenna, and measurements were performed by the free space method. Specifically, under an environment at the temperature of 24.8° C. and the relative humidity of 48%, for the molded bodies obtained in Examples and Comparative Examples, reflection losses were measured at a measurement frequency of 76.5 GHz in a state where the injection direction (MD direction) and the electric field direction of the electromagnetic wave (y direction in FIG. 1) were parallel.

### (Transmission Loss TL)

As an indicator of electromagnetic wave absorption performance, transmission loss (dB) in the millimeter wave frequency band was measured by the following method. A vector network analyzer (VNA) was used as the measuring instrument, APC-7 (manufactured by Kanto Electronics Application and Development Inc.) was used as the measurement jig, and an E-band antenna (WR-12) was used as the antenna, and measurements were performed by the free space method. Specifically, under an environment at the temperature of 24.8° C. and the relative humidity of 48%, for the molded bodies obtained in Examples and Comparative Examples, transmission losses were measured at a measurement frequency of 76.5 GHz in a state where the injection direction (MD direction) and the electric field direction of the electromagnetic wave (y direction in FIG. 1) were parallel.

Electromagnetic wave absorption performance was evaluated according to the following criteria.
∘ (Good): Reflection loss of −5 dB or less and transmission loss of −15 dB or less
Δ (Usable): Reflection loss of −4 dB or less and transmission loss of −10 dB or less
x (Not usable): Reflection loss greater than −4 dB or transmission loss greater than −10 dB

### [Flexibility]

As an indicator of flexibility, Shore D hardness was measured by using a durometer hardness tester (D type) manufactured by Kobunshi Keiki Co., Ltd. according to ISO 7619-1:2010. Shore D hardness (after 5 seconds) was measured by bringing the indenter into contact with a test specimen consisting of two stacked molded bodies having a thickness of 3 mm obtained by the method, and reading the scale after 5 seconds.

### (Evaluation Criteria)

◯ (Good): Shore D hardness (after 5 seconds) less than 40
Δ (Usable): Shore D hardness (after 5 seconds) of 40 or more and less than 50
x (Not usable): Shore D hardness (after 5 seconds) of 50 or more

### [Heat Resistance]

As an indicator of heat resistance, the deflection temperature under load was measured using a Heat Distortion Tester manufactured by Yasuda Seiki in accordance with ISO 178:2019. By using the thermoplastic resin composition, injection molding was performed with an injection molding machine (manufactured by Toshiba Machine Co., Ltd.) at a cylinder set temperature of 220° C. and a mold temperature of 40° C., and multipurpose test specimens (thickness 4 mm) were prepared in accordance with ISO 10724-1:1998. By using the multipurpose test specimens, the deflection temperature under load was measured under the condition of a load of 0.45 MPa.

### (Evaluation Criteria)

◯ (Good): Deflection temperature under load of 50° C. or more
Δ (Usable): Deflection temperature under load of 40° C. or more and less than 50° C.
x (Not usable): Deflection temperature under load of less than 40° C.

TABLE 5

| | | | Example | Example | Example | Example | Example |
|---|---|---|---|---|---|---|---|
| | | | 1 | 2 | 3 | 4 | 5 |
| Thermoplastic | Olefin | A-1 | 68 | | | 68 | 68 |
| resin | Elastomer (A) | A-2 | | 68 | | | |
| composition | | A-3 | | | 68 | | |
| | Styrene | B1-1 | 20 | 20 | 20 | | |
| | Elastomer (B1) | B1-2 | | | | 20 | |
| | | B1-3 | | | | | 20 |
| | | B1-4 | | | | | |
| | | B1-5 | | | | | |
| | | B1-6 | | | | | |
| | | B1-7 | | | | | |
| | | B1-8 | | | | | |
| | Olefin | B2-1 | | | | | |
| | Elastomer (B2) | B2-2 | | | | | |
| | | B2-3 | | | | | |
| | | B2-4 | | | | | |
| | Carbon | C-1 | 2 | 2 | 2 | 2 | 2 |
| | Nanotube (C) | C-2 | | | | | |
| | | C-3 | | | | | |
| | Carbon | D-1 | 10 | 10 | 10 | 10 | 10 |
| | Black (D) | D-2 | | | | | |
| | | D-3 | | | | | |
| Evaluation of | Electromagnetic | Reflection | −6 | −6 | −4 | −6 | −6 |
| molded body | wave absorption | loss | | | | | |
| | | Transmission | −21 | −18 | −24 | −20 | −20 |
| | | loss | | | | | |
| | | Judgment | ∘ | ∘ | Δ | ∘ | ∘ |
| | Flexibility | | 35 | 41 | 37 | 32 | 31 |
| | (Durometer hardness) | | ∘ | Δ | ∘ | ∘ | ∘ |
| | Heat resistance | | 55 | 58 | 61 | 53 | 52 |
| | (Deflection temperature | | ∘ | ∘ | ∘ | ∘ | ∘ |
| | under load) | | | | | | |
| | | | Example | Example | Example | Example | Example |
| | | | 6 | 7 | 8 | 9 | 10 |
| Thermoplastic | Olefin | A-1 | 68 | 68 | 68 | 68 | 68 |
| resin | Elastomer (A) | A-2 | | | | | |
| composition | | A-3 | | | | | |
| | Styrene | B1-1 | | | | | |
| | Elastomer (B1) | B1-2 | | | | | |
| | | B1-3 | | | | | |
| | | B1-4 | 20 | | | | |
| | | B1-5 | | 20 | | | |
| | | B1-6 | | | 20 | | |
| | | B1-7 | | | | 20 | |
| | | B1-8 | | | | | 20 |
| | Olefin | B2-1 | | | | | |
| | Elastomer (B2) | B2-2 | | | | | |
| | | B2-3 | | | | | |
| | | B2-4 | | | | | |
| | Carbon | C-1 | 2 | 2 | 2 | 2 | 2 |
| | Nanotube (C) | C-2 | | | | | |
| | | C-3 | | | | | |
| | Carbon | D-1 | 10 | 10 | 10 | 10 | 10 |
| | Black (D) | D-2 | | | | | |
| | | D-3 | | | | | |
| Evaluation of | Electromagnetic | Reflection | −6 | −6 | −6 | −4 | −6 |
| molded body | wave absorption | loss | | | | | |
| | | Transmission | −22 | −21 | −20 | −20 | −19 |
| | | loss | | | | | |
| | | Judgment | ∘ | ∘ | ∘ | Δ | ∘ |

| | | | | | |
|---|---|---|---|---|---|
| Flexibility | 29 | 30 | 29 | 46 | 39 |
| (Durometer hardness) | ∘ | ∘ | ∘ | Δ | ∘ |
| Heat resistance | 50 | 45 | 42 | 62 | 43 |
| (Deflection temperature | ∘ | Δ | Δ | ∘ | Δ |
| under load) | | | | | |

TABLE 6

| | | | Example | Example | Example | Example | Example | Example |
|---|---|---|---|---|---|---|---|---|
| | | | 11 | 12 | 13 | 14 | 15 | 16 |
| Thermoplastic | Olefin | A-1 | 68 | 68 | 68 | 68 | 68 | 68 |
| resin | Elastomer (A) | A-2 | | | | | | |
| composition | | A-3 | | | | | | |
| | Styrene | B1-1 | | | | | 20 | 20 |
| | Elastomer (B1) | B1-2 | | | | | | |
| | | B1-3 | | | | | | |
| | | B1-4 | | | | | | |
| | | B1-5 | | | | | | |
| | | B1-6 | | | | | | |
| | | B1-7 | | | | | | |
| | | B1-8 | | | | | | |
| | Olefin | B2-1 | 20 | | | | | |
| | Elastomer (B2) | B2-2 | | 20 | | | | |
| | | B2-3 | | | 20 | | | |
| | | B2-4 | | | | 20 | | |
| | Carbon | C-1 | 2 | 2 | 2 | 2 | | |
| | Nanotube (C) | C-2 | | | | | 2 | |
| | | C-3 | | | | | | 2 |
| | Carbon | D-1 | 10 | 10 | 10 | 10 | 10 | 10 |
| | Black (D) | D-2 | | | | | | |
| | | D-3 | | | | | | |
| Evaluation of | Electromagnetic | Reflection | −6 | −4 | −6 | −6 | −5 | −5 |
| molded body | wave absorption | loss | | | | | | |
| | | Transmission | −22 | −27 | −21 | −22 | −24 | −19 |
| | | loss | | | | | | |
| | | Judgment | ∘ | Δ | ∘ | ∘ | ∘ | ∘ |
| | Flexibility | | 37 | 39 | 35 | 45 | 34 | 34 |
| | (Durometer hardness) | | ∘ | ∘ | ∘ | Δ | ∘ | ∘ |
| | Heat resistance | | 45 | 47 | 41 | 48 | 55 | 55 |
| | (Deflection temperature | | | | | | | |
| | under load) | | Δ | Δ | Δ | Δ | ∘ | ∘ |
| | | | Example | Example | Example | Example | Example | Example |
| | | | 17 | 18 | 19 | 20 | 21 | 22 |
| Thermoplastic | Olefin | A-1 | 68 | 68 | 73 | 61 | 60 | 60 |
| resin | Elastomer (A) | A-2 | | | | | | |
| composition | | A-3 | | | | | | |
| | Styrene | B1-1 | 20 | 20 | 20 | 32 | 25 | 25 |
| | Elastomer (B1) | B1-2 | | | | | | |
| | | B1-3 | | | | | | |
| | | B1-4 | | | | | | |
| | | B1-5 | | | | | | |
| | | B1-6 | | | | | | |
| | | B1-7 | | | | | | |
| | | B1-8 | | | | | | |
| | Olefin | B2-1 | | | | | | |
| | Elastomer (B2) | B2-2 | | | | | | |
| | | B2-3 | | | | | | |
| | | B2-4 | | | | | | |
| | Carbon | C-1 | 2 | 2 | 2 | 2 | 5 | 2 |
| | Nanotube (C) | C-2 | | | | | | |
| | | C-3 | | | | | | |
| | Carbon | D-1 | | | 5 | 5 | 10 | 13 |
| | Black (D) | D-2 | 10 | | | | | |
| | | D-3 | | 10 | | | | |
| Evaluation of | Electromagnetic | Reflection | −5 | −5 | −7 | −5 | −8 | −7 |
| molded body | wave absorption | loss | | | | | | |
| | | Transmission | −23 | −21 | −12 | −17 | −11 | −14 |
| | | loss | | | | | | |
| | | Judgment | ∘ | ∘ | Δ | ∘ | Δ | Δ |

| | | | | | | |
|---|---|---|---|---|---|---|
| Flexibility | 37 | 39 | 32 | 28 | 48 | 41 |
| (Durometer hardness) | ∘ | ∘ | ∘ | ∘ | Δ | Δ |
| Heat resistance | 54 | 54 | 51 | 48 | 62 | 60 |
| (Deflection temperature | | | | | | |
| under load) | ∘ | ∘ | ∘ | Δ | ∘ | ∘ |

TABLE 7

| | | | Compar- | Compar- | Compar- | Compar- | Compar- | Compar- | Compar- | Compar- |
|---|---|---|---|---|---|---|---|---|---|---|
| | | | ative | ative | ative | ative | ative | ative | ative | ative |
| | | | Example 1 | Example 2 | Example 3 | Example 4 | Example 5 | Example 6 | Example 7 | Example 8 |
| Thermoplastic | Olefin | A-3 | | 68 | 88 | 78 | 48 | 62 | 76 | 58 |
| resin | Elastomer (A) | A'-1 | 68 | | | | | | | |
| composition | Styrene | B1-1 | 20 | | | 10 | 40 | 20 | 20 | 20 |
| | Elastomer (B1) | | | | | | | | | |
| | Olefin | B2′-1 | | 20 | | | | | | |
| | Elastomer (B2) | | | | | | | | | |
| | Carbon | C-1 | 2 | 2 | 2 | 2 | 2 | 8 | 2 | 2 |
| | Nanotube (C) | | | | | | | | | |
| | Carbon | D-1 | 10 | 10 | 10 | 10 | 10 | 10 | 2 | 20 |
| | Black (D) | | | | | | | | | |
| Evaluation of | Electromagnetic | Reflection | −3 | −4 | −4 | −6 | −5 | −9 | −3 | −7 |
| molded body | wave | loss | | | | | | | | |
| | absorption | Transmission | −32 | −13 | −20 | −20 | −16 | −7 | −28 | −13 |
| | | loss | | | | | | | | |
| | | Judgment | x | Δ | Δ | ∘ | ∘ | x | x | Δ |

| | | | | | | | | |
|---|---|---|---|---|---|---|---|---|
| Flexibility | 55 | 53 | 62 | 53 | 24 | 56 | 30 | 53 |
| (Durometer hardness) | x | x | x | x | ∘ | x | ∘ | x |
| Heat resistance | 52 | 49 | 58 | 53 | 25 | 59 | 27 | 55 |
| (Deflection temperature | ∘ | Δ | ∘ | ∘ | x | ∘ | x | ∘ |
| under load) | | | | | | | | |

From the above evaluation results, it is confirmed that the thermoplastic resin composition of the invention and the molded body using the same have favorable electromagnetic wave absorption and flexibility, and are also excellent in heat resistance. In particular, since the thermoplastic resin composition and the molded body using the same are excellent in reflection loss and transmission loss in the specific frequency band of 60 GHz to 90 GHz referred to as millimeter waves, it can be said that the thermoplastic resin composition and the molded body using the same can be suitably used for molded bodies for millimeter wave absorbers.

1. A thermoplastic resin composition for an electromagnetic wave absorber, the thermoplastic resin comprising: 50% by mass to 80% by mass of Olefin Elastomer (A) having a tensile elongation rate at break of 400% to 700% measured according to ISO 37:2017; 15% by mass to 35% by mass of Elastomer (B) comprising at least one selected from a group consisting of Styrene Elastomer (B1) and Olefin Elastomer (B2) having a tensile elongation rate at break of 800% or more measured according to ISO 37:2017; 0.5% by mass to 5% by mass of Carbon Nanotube (C); and 3% by mass to 15% by mass of Carbon Black (D).

2. The thermoplastic resin composition for the electromagnetic wave absorber as claimed in claim 1, wherein Elastomer (B) comprises Styrene Elastomer (B1), and
Styrene Elastomer (B1) comprises at least one selected from a group consisting of a styrene-ethylene-butylene-styrene block copolymer, a styrene-ethylene-propylene block copolymer, a styrene-ethylene-propylene-styrene block copolymer, and a styrene-ethylene-ethylene-propylene-styrene block copolymer.

3. The thermoplastic resin composition for the electromagnetic wave absorber as claimed in claim 1, wherein Elastomer (B) comprises Styrene Elastomer (B1), and
a content of a styrene structure in Styrene Elastomer (B1) is 15% by mass to 35% by mass.

4. The thermoplastic resin composition for the electromagnetic wave absorber as claimed in claim 1, wherein Elastomer (B) includes Olefin Elastomer (B2), and
Olefin Elastomer (B2) comprises an ethylene-α-olefin copolymer.

5. A molded body, formed by using the thermoplastic resin composition for the electromagnetic wave absorber as claimed in claim 1.
